(19) United States
(12) Patent Application Publication
(10) Pub. No.: US 2025/0306071 A1
(43) Pub. Date: Oct. 2, 2025

(54) DETERMINING AN INSULATION RESISTANCE

(71) Applicant: AVL DiTest GmbH, Graz (AT)

(72) Inventors: Lukas Fischer, Aldrans (AT); Roman Riegler, Tulfes (AT); Jonas Schulz, Graz (AT)

(21) Appl. No.: 19/088,236

(22) Filed: Mar. 24, 2025

(30) Foreign Application Priority Data
Mar. 27, 2024 (AT) A50268/2024

(51) Int. Cl. G01R 27/02; G01R 22/06; G01R 27/08; G01R 27/26; G01R 35/00

(52) U.S. Cl. CPC G01R 27/025; G01R 22/06; G01R 27/08; G01R 35/005; G01R 27/2605

(57) ABSTRACT

To significantly and effectively reduce the effects of fluctuations in a measurement current on the determination of an insulation resistance in a high-voltage system, a method for determining an insulation resistance in a high-voltage system and an associated measuring system are proposed, in which, during a ramp-up of a test voltage to a predefined target value, first an electrical charge of the high-voltage system to be tested and/or the component to be tested is determined and then a capacitance value for the high-voltage system to be tested and/or the component to be tested is estimated from the determined charge, and in which, a correction current is determined from the estimated capacitance value and from a temporal deviation of a measured measurement voltage from the predefined target value of the test voltage during a measuring phase, in which the predefined target value is reached and approximately maintained by the test voltage, the correction current being used to correct the respective measured measurement current, and then the insulation resistance is derived from the corrected measurement current and the measured voltage. At least the derived insulation resistance can then be output and displayed.

The present invention relates to a method for determining an insulation resistance in a high-voltage system and an associated measuring system for determining an insulation resistance. A test voltage with a predefined constant target value is applied to the high-voltage system to be tested and/or a component to be tested, and a measurement current caused by the test voltage and a measurement voltage currently applied to the high-voltage system to be tested and/or to the component to be tested are measured.

### PRIOR ART

High-voltage components or HV components, such as rechargeable batteries (high-voltage battery), power electronics components (e.g., an inverter for controlling the electric drive motor, a voltage converter or DC-DC converter, etc.), on-board chargers (OBC) and other auxiliary units (e.g., pumps, heating elements, etc.), which are electrically connected to the powerful high-voltage battery via a large number of high-voltage cables, are used, for example, in electrified vehicles. These HV components form the so-called high-voltage system or HV system of the electrified vehicle, which is usually operated with an operating voltage of over 60 V, usually in a range of several 100 volts (e.g., between 200 V and 1 kV). The HV battery and the connected HV components are therefore electrically isolated from other vehicle parts, in particular from the vehicle chassis. In most cases, the HV system of an electrified vehicle is implemented as a non-earthed, so-called IT (Isolé Terre) network and is usually completely galvanically isolated from a vehicle reference potential or vehicle ground.

A sufficiently high resistance of the insulation of the HV system or the HV components, in particular the HV cables and, if applicable, the HV plug connections that connect the components, prevents unwanted current flows and protects people in the vicinity of an electrified vehicle from corresponding contact with the HV system. Typically, the insulation resistance is in the range of one hundred megaohms to gigaohms to ensure that there is no danger. However, insulation resistance can change due to aging processes, moisture, contamination, damage, radiation and chemical or physical influences. To ensure that there is no danger, minimum insulation resistances are prescribed. Therefore, HV systems in electrified vehicles, for example, are monitored during operation by built-in automatic insulation monitors to detect possible fault currents and to prevent potential danger to the user. Furthermore, the condition of the insulation of the HV system is checked by an insulation measurement, e.g., during a maintenance service, wherein an insulation resistance of the HV system or individual HV components (e.g., HV cable, charging socket, power electronics, etc.) is usually determined using a measuring system, e.g., an insulation measuring device, which can be connected to the HV system being checked or to the HV component to be checked via measuring contacts. The measurement of insulation resistance is usually used to qualitatively assess the condition of the insulation of the HV system, in particular the HV cables and the insulation inside the HV system.

To check the integrity of the insulation in the HV system, a constant DC voltage is usually applied as a test voltage to the HV system to be tested or HV component to be tested. The test voltage should be at least in the range of the battery voltage of the electrified vehicle, ideally slightly higher. Typically, a test voltage with a predefined target value of 500 volts is used. A current induced by the applied test voltage, a so-called leakage current, is then measured to derive the insulation resistance from the value of the applied test voltage and the measured leakage current. In the initial phase of the measurement, in which, for example, the test voltage increases to the predefined value, the measured current usually contains parasitic current components in addition to the leakage current. The parasitic current components include, for example, a capacitive current component or charging current, which in particular includes a current for charging or recharging the capacitors in the HV system or the insulation, and an absorptive current component, which flows due to a reorientation of molecules in the insulation material of the insulation. These parasitic current components can be relatively high compared to the leakage current, but usually decay relatively quickly (e.g., exponentially). Only after a decay time does the measured current correspond to the leakage current and can the insulation resistance be determined.

However, in systems with relatively high operating voltages, such as in HV systems, a relatively small leakage current, for example in the range of a few microamperes or usually less, flows through the insulation. These very small leakage currents must be quantified by the measuring system or the insulation measuring device. This measuring system represents, for example, a multifunctional measuring device and, in addition to an adjustable or regulated voltage source as a voltage generator, from which the test voltage is generated with a predefined constant target value, has at least one ammeter with which the current caused by the test voltage can be measured in order to determine the insulation resistance. In addition, the measuring system can also have a voltmeter, for example to measure the voltage applied to the HV system or component to be tested or its course, especially when the test voltage is ramping up.

In the case of capacitances, especially relatively large capacitances, in the HV system to be tested, regulating the test voltage to the desired constant target value can be difficult. Especially if the test voltage is generated, for example, by a regulated voltage source or by a voltage regulator as a voltage generator and is to be regulated to the desired constant target value, drift voltages and/or fluctuations in the test voltage can occur. These drift voltages are relatively slow and are caused, for example, by low-frequency noise (e.g., 1/f noise) in the feedback control of the voltage source. This means that the test voltage contains, in addition to a direct voltage component which corresponds to the predefined target value, a low-frequency alternating voltage component caused by the drift voltages and/or fluctuations. Due to the low-frequency alternating voltage component with which the test voltage deviates from the target value, the capacitances in the HV system to be tested can cause relatively large capacitive current components or charging currents, which cover the relatively small leakage current. This falsifies the measurement of the leakage current and significantly hinders the correct determination of the insulation resistance of the HV system to be tested.

### REPRESENTATION OF THE INVENTION

The invention is therefore based on the object of specifying a method and an associated device, with which an insulation resistance in a HV system and/or a HV component can be determined as accurately and authentically as possible.

These and other objects are achieved by a measuring device according to the independent claims. Advantageous embodiments of the present invention are described in the dependent claims.

According to the invention, the object is achieved by a method of the type specified at the outset, wherein an electrical charge of the high-voltage system to be tested and/or the component to be tested is determined during a ramp-up of the test voltage to a predefined constant target value, wherein a capacitance value for the high-voltage system to be tested and/or for the component to be tested is also estimated from the determined charge, wherein a correction current is then determined during a measuring phase from the estimated capacitance value and from a temporal deviation of the measured measurement voltage from the predefined target value of the test voltage, the correction current being used to correct the respectively measured measurement current, and wherein the insulation resistance is derived from the corrected measurement current and the measured measurement voltage. This significantly and effectively reduces the fluctuations in the measurement current, particularly those caused by the voltage drift of the test voltage. The insulation resistance of the HV system or HV component to be tested can thus be determined much more accurately and largely without distortion, since the correction current largely compensates for the influence of the charging currents or fluctuations in the measurement current caused by the voltage drift.

Ideally, the electrical charge of the HV system and/or component to be tested is determined by integrating the measured measurement current during the ramp-up of the test voltage to the predefined constant target value to estimate a capacitance value of the HV system and/or component to be tested from the electrical charge. For this purpose, in a preferred embodiment of the method according to the invention, a first and a second voltage value of the measurement voltage can be predetermined, between which the electrical charge of the high-voltage system to be tested and/or the component to be tested is determined. This means that during the ramping up of the test voltage, the integration of the measurement current begins when the first voltage value is reached by the measurement voltage and ends when the second voltage value is reached by the measurement voltage, thereby determining the charging or discharging of the HV system to be tested or component to be tested, which is caused by applying and ramping-up the test voltage, to estimate the capacitance of the HV system to be tested or component to be tested.

A further embodiment of the method according to the invention provides that for estimating the capacitance value of the high-voltage system to be tested and/or the component to be tested, a third voltage value of the measurement voltage is predetermined, which is greater than the first voltage value of the measurement voltage and less than the second voltage value of the measurement voltage. The electrical charge of the high-voltage system to be tested and/or the component to be tested between the first and the third voltage value and the electrical charge of the high-voltage system to be tested and/or the component to be tested between the third and the second voltage value are then determined, and a respective capacitance value of the high-voltage system to be tested and/or the component to be tested is estimated from the determined charges. This can be used, for example, to determine the influence of a parallel resistance or to very easily improve the accuracy of the estimation of the capacitance value of the HV system to be tested and/or component to be tested.

It is also advantageous if at least the derived insulation resistance is output and displayed. For this purpose, a display unit can be provided in a measuring system for determining the insulation system.

Ideally, a measurement of the measurement current and a measurement of the measurement voltage are carried out simultaneously. This makes it much easier, for example, to estimate the capacitance by integrating the measurement current and continuously correcting the measurement current as well as determining the insulation resistance.

It is also advantageous if, during the ramp-up of the test voltage to the predefined constant target value, a temporal change in the measurement voltage applied to the high-voltage system to be tested and/or to the component to be tested is limited when the test voltage is ramping up to the predefined target value.

The measurement of the measurement current and/or the measurement voltage can be carried out either continuously or by time-discrete sampling. In particular, in the case of time-discrete sampling of the measurement current, it can be integrated particularly easily during the ramp-up of the test voltage.

The object is further achieved by a measuring system for determining an insulation resistance in a high-voltage system. For this purpose, the measuring system can be connected to the high-voltage system to be tested and/or to a component of the high-voltage system to be tested and has at least one voltage source for generating a test voltage with a predefined constant target value, an ammeter for measuring a measurement current caused by the test voltage and a voltage meter for measuring a measurement voltage applied to the high-voltage system to be tested and/or the component to be tested. Furthermore, the measuring system has an evaluation unit which is designed to determine an electrical charge of the high-voltage system to be tested and/or the component to be tested while the test voltage is ramping up to the predefined constant target value and to estimate a capacitance value of the high-voltage system to be tested and/or the component to be tested from the determined charge. This can be done, for example, by integrating the measured measurement current, ideally between a first and a second voltage value of the measurement voltage. Furthermore, the evaluation unit is designed to determine a correction current for correcting the measurement current measured by the ammeter during a measuring phase from the determined capacitance value and from a temporal deviation of the measurement voltage measured by the voltmeter from the predefined constant target value of the test voltage and to derive the insulation resistance from the corrected measurement current and the measured measurement voltage.

It is advantageous if the measured value acquisition by the ammeter and the measured value acquisition by the voltmeter as well as the evaluation unit are designed to be microcontroller-based. As a result, the method according to the invention can be carried out, for example, almost in real time.

### BRIEF DESCRIPTION OF THE FIGURES

The present invention will be described in greater detail below with reference to FIGS. 1 to 4, which by way of example show schematic and non-limiting advantageous embodiments of the invention. In the figures:

FIG. 1 shows a measuring system for determining an insulation resistance in a high-voltage system

FIG. 2 shows a sequence of the method for determining an insulation resistance in a high-voltage system

FIG. 3 shows a course of a measured measurement voltage during the method for determining the insulation resistance in the high-voltage system

FIG. 4 shows courses of the measured measurement voltage as well as of a measured measurement current, a correction current and a corrected measurement current and of a derived resistance during a measuring phase

### EXECUTION OF THE INVENTION

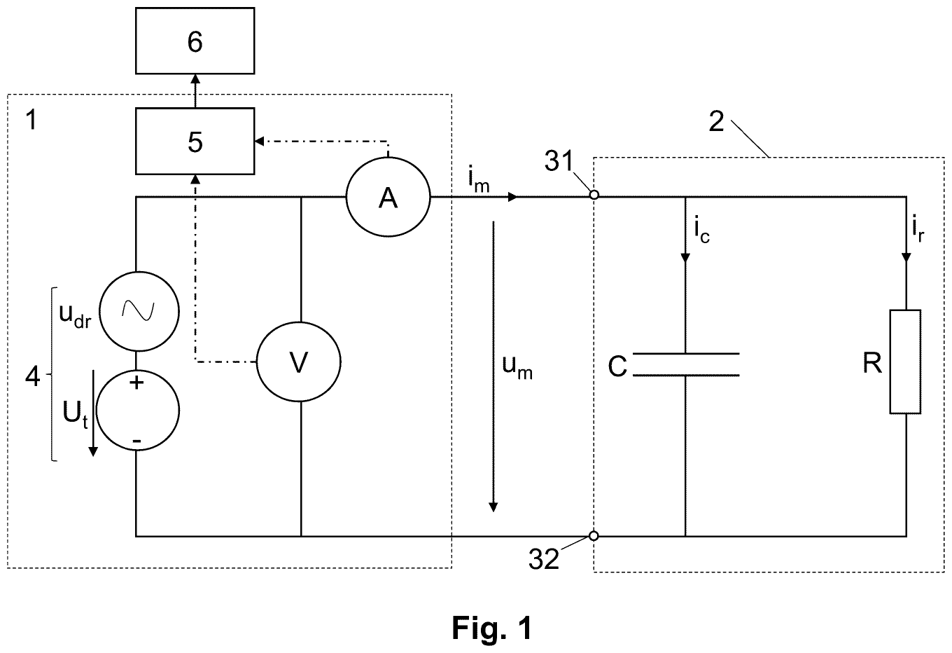

FIG. 1 shows exemplary and schematically a measuring system 1 with which an insulation resistance R in a high-voltage system 2 or in a HV system 2 can be determined. The HV system 2 to be tested or the component 2 to be tested (e.g., HV cable, charging socket, power electronics, etc.) of the HV system is shown as a parallel connection of a capacitor C and a resistor R, wherein the resistor R symbolizes the insulation resistance R to be measured and the capacitor C stands for the capacitances in the HV system 2 or in the HV component 2. The measuring system 1 can be connected to the HV system 2 to be tested or the HV component 2 to be tested via measuring contacts 31, 32. The measuring contacts 31, 31 can be configured, for example, as test probes which are connected to measuring points (e.g., positive high-voltage connection of the HV system 2 to be tested or the component to be tested and chassis as reference potential, negative high-voltage connection of the HV system 2 to be tested or the component to be tested and chassis as reference potential). The measuring contacts 31, 32 can also be designed as connections and/or terminals, for example to be connected to a suitable measuring socket (e.g., HV+ socket, HV− socket) or to be clamped to a measuring point (e.g., chassis of the vehicle).

Furthermore, the measuring system 1 comprises a voltage source 4, which generates a test voltage with a predefined target value Uₜ (e.g., 500 volts). The test voltage is applied to the HV system 2 to be tested or the component 2 to be tested between the measuring contacts 31, 32 and causes a measurement current iₘ. To measure the measurement current iₘ, the measuring system 1 comprises an ammeter A, which is arranged in series with the voltage source 4. Furthermore, the measuring system 1 comprises a voltmeter V, which is arranged parallel to the voltage source 4. For example, the voltmeter V can be used to measure the current voltage uₘ applied to the HV system 2 to be tested or the HV component 2 to be tested.

When the test voltage ramps up to the predefined target value Uₜ and the capacitance C of the HV system 2 or the HV component 2 is thereby charged (i.e., is charged up or discharged by the test voltage), the measurement current iₘ—as shown in FIG. 1 as an example—divides into a charging current i_{c} and into a leakage current iᵣ. Ideally, the charging current i_{c} decreases with increasing electrical charge of the capacitor C and has a value of zero when the capacitor C is fully charged, so that the measurement current iₘ largely corresponds to the leakage current iᵣ. In a measuring phase MP, the test voltage ideally has the predefined target value Uₜ and maintains it constantly, so that a voltage with the predefined target value Uₜ is applied to the HV system 2 to be tested or to the component 2 to be tested. Reaching the target value Uₜ of the test voltage on the HV system 2 to be tested or on the component 2 to be tested can be determined, for example, using the measurement voltage uₘ measured by the voltmeter V. The measurement current iₘ measured in the measuring phase MP can then be used to determine the insulation resistance R—ideally according to Ohm's law.

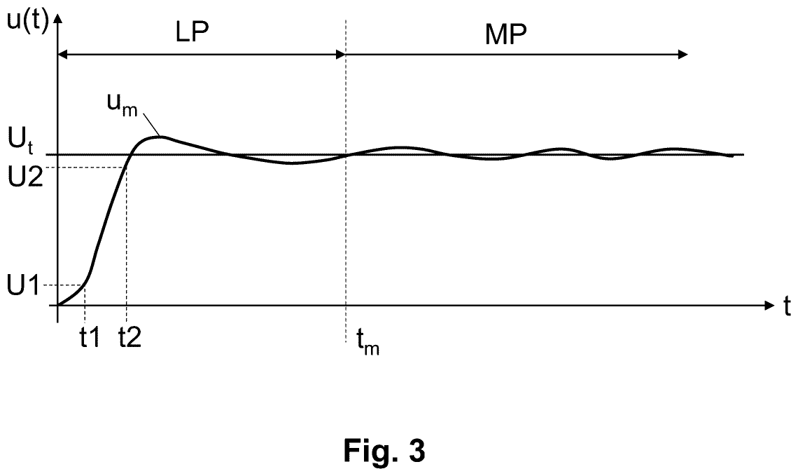

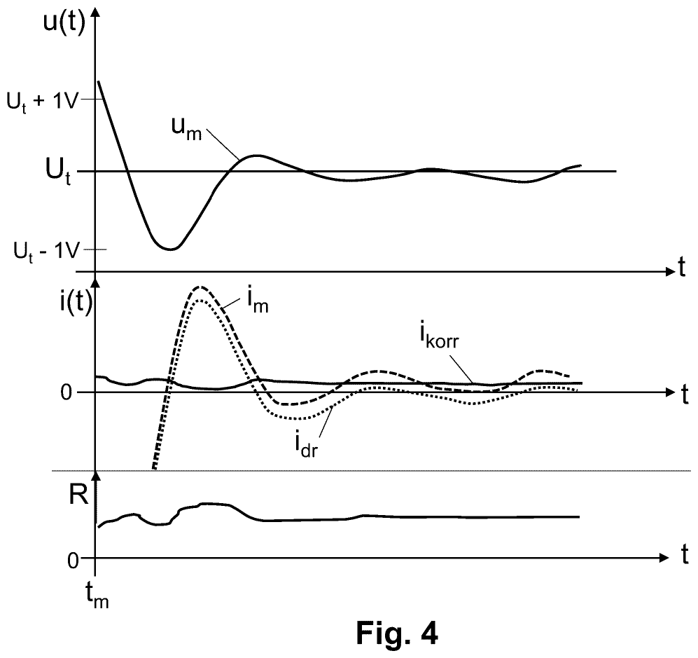

In a real measuring system 1, especially when using a regulated voltage source 4 or a voltage regulator as voltage source 4, the voltage source 4 can exhibit slow drifts and fluctuations u_{dr}. These are exemplified in FIG. 1 by an alternating voltage source or drift voltage u_{dr}. The drifts and fluctuations u_{dr} are usually caused by low-frequency noise (e.g., in the range of approx. 1 Hertz) in a feedback control of the voltage source 4, so that the test voltage also in the measuring phase MP fluctuates with very small deviations u_{dr} around the predefined target value Uₜ—as will be exemplified below on the basis of FIGS. 3 and 4. In particular, with a relatively large capacitance C (e.g., in the range of approx. 1 μFarad or greater) in the HV system 2, the drift voltage u_{dr} furthermore causes-even after charging or recharging the capacitor C in the HV system 2 or in the measuring phase MP-relatively large capacitive charging currents i_{c}, which falsify the measured measurement current iₘ. Since, especially with a very high insulation resistance R, for example in the megaohm range, the leakage current iᵣ is relatively small, the relatively small leakage current iᵣ can be covered by the capacitive charging currents i_{c}, which may lead to an incorrect determination of the insulation resistance R.

To compensate for any influence of the charging currents i_{c}, the measuring system 1 comprises an evaluation unit 5. The evaluation unit 5 can be microcontroller-based, like a measured value acquisition by the ammeter A and by the voltmeter V. The evaluation unit 5 is configured, during the ramp-up LP of the test voltage to the predefined constant target value Uₜ, to determine the electrical charge of the high-voltage system 2 to be tested and/or the component 2 to be tested between a first voltage value U1 of the measurement voltage uₘ and a second voltage value U2 of the measurement voltage uₘ by integrating the measurement current iₘ measured largely simultaneously with the measurement voltage uₘ measured and to use this to estimate a value of the capacitance C. Furthermore, the evaluation unit 5 is configured, during the measuring phase MP—i.e., after the target value Uₜ has been reached by the test voltage—to determine a correction current i_{dr} from the determined capacitance value C and a temporal deviation of the measurement voltage uₘ measured by the voltmeter V from the predefined constant target value Uₜ of the test voltage. This correction current i_{dr} is used by the evaluation unit 5 to correct the measurement current iₘ measured by the ammeter A. In addition, the evaluation unit 5 is configured to derive the insulation resistance from the corrected measurement current iₖₒᵣᵣ. The evaluation unit 5 receives the currently measured values of the measurement current iₘ from the ammeter A as well as the currently measured values of the measurement voltage uₘ from the voltmeter V. For this purpose the measurement of the measurement current iₘ by the ammeter A and the measurement of the measurement voltage uₘ by the voltmeter V can be carried out continuously or by time-discrete sampling, for example.

Furthermore, a display unit 6 can be provided, on which at least the insulation resistance R derived from the corrected measurement current iₖₒᵣᵣ can be displayed. The insulation resistance R can be specified, for example, absolutely in megaohms and/or as measured resistance R related to the voltage in Q/V. In addition, an evaluation of the measured insulation resistance R (e.g., insulation resistance R sufficient; insulation resistance R too small, etc.) could also be indicated on the display unit 6.

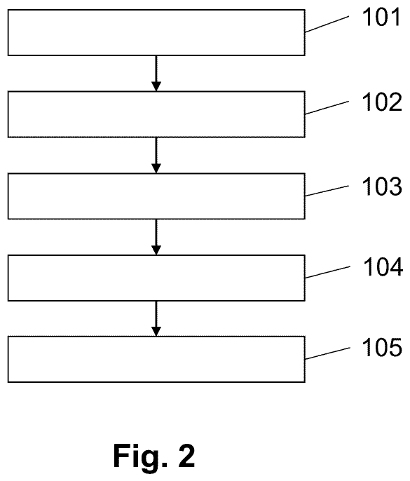

FIG. 2 shows an example of a sequence of the method for determining an insulation resistance R in a high-voltage system 2. To carry out the method, the measuring system 1 is connected to the HV system 2 to be tested or to the component of the HV system 2 to be tested via the measuring contacts 31, 32. The test voltage generated by the voltage source 4 of the measuring system 1 is applied to the HV system 2 to be tested or to the component to be tested via the measuring contacts 31, 32. The test voltage is ramped up to the predefined target value Uₜ which is reached in the measuring phase MP and is held at this value apart from relatively small deviations due to the drift voltage u_{dr}. The test voltage causes a measurement current iₘ which can be measured by the ammeter A of the measuring system 1 continuously or by time-discrete sampling. The measurement voltage uₘ currently present on the HV system 2 to be tested or on the component to be tested is measured largely simultaneously by the voltmeter V of the measuring system 1, which makes it possible to check when the target value Uₜ of the test voltage from the HV system 2 to be tested or the component to be tested is reached and largely—except for the deviations due to the voltage drift u_{dr}—maintained and the measuring phase MP can begin.

In a first determination step 101, while the test voltage is ramping up to the predefined target value Uₜ, the electrical charge of the high-voltage system 2 to be tested or the component to be tested is determined in the evaluation unit 5. This means that, for example, the charge of a non-charged high-voltage system 2 or a component to be tested is determined by applying the test voltage. Alternatively, a discharge or a change in the charge of a charged high-voltage system 2 or a component to be tested could also be determined by applying the test voltage. For this purpose, the measured measurement current iₘ is, for example, integrated between two predetermined voltage values U1, U2. The first voltage value U1, at which the integration of the measurement current iₘ is started, can be, e.g., 20% of the target value Uₜ of the test voltage. The second voltage value U2, at which the integration of the measurement current iₘ is terminated again, can be, e.g., 90% of the target value Uₜ of the test voltage. The electrical charge Q of the high-voltage system 2 to be tested or of the component to be tested is then given, for example, by the following formula (1).

$$Q = {\int }_{t 1}^{t 2} i ( t ) dt , \qquad ( 1 )$$

wherein i(t) is the measured measurement current iₘ or a sequence of time-discretely sampled measured values of the measurement current iₘ when ramping up the test voltage. The times t1, t2, between which the current iₘ is integrated, correspond to the times t1, t2 at which the measurement voltage uₘ reaches the predetermined voltage values U1, U2.

This can be seen, for example, in FIG. 3, which shows a temporal progression of the measurement voltage uₘ during the execution of the method, wherein, for example, a non-charged HV system 2 to be tested or a component to be tested with a relatively large capacitance C (e.g., 1 μFarad) and a parallel resistance R in the high-ohmic range (e.g., 1 GΩ) was assumed. For this purpose, the time t in seconds is shown on the x-axis and the voltage U (e.g., in volts) on the y-axis. The y-axis furthermore shows the constant target value Uₜ of the test voltage. The target value Uₜ can be 500 V, for example. During the ramp-up LP, the test voltage is ramped up to the target value Uₜ. Ideally, during the ramp-up LP of the test voltage, a temporal change—i.e., du(t)/dt—of the voltage applied to the HV system 2 to be tested or the component to be tested, which corresponds to the measurement voltage uₘ, is limited and the HV system 2 to be tested or the component to be tested is charged, for example with a limited, ideally constant current. If, at a time tₘ, the target value Uₜ is reached and kept constant, except for the deviations due to the voltage drift u_{dr}, the measuring phase MP starts. This means that the measuring phase MP starts when the voltage fluctuations have fallen below a predetermined threshold or the test voltage has been adjusted accordingly.

In FIG. 3, the first voltage value U1 (e.g., 20% of the target value Uₜ of the test voltage), which is measured by the voltmeter V at a time t1, is also plotted by way of example. At this voltage value U1 or at this time t1, the evaluation unit 5 starts to integrate the measured measurement current iₘ. Furthermore, in FIG. 3, the second voltage value U2 (e.g., 90% of the target value Uₜ of the test voltage) is also plotted. This is reached at the time t2 and the evaluation unit 5 terminates the integration of the measured measurement current iₘ at this time t2 to determine the charge Q of the HV system 2 to be tested or the component to be tested.

In an estimation step 102, a value for the capacitance C of the HV system 2 to be tested or the component to be tested is estimated from the determined charge Q of the HV system 2 to be tested or the component to be tested. This is done by neglecting the (relatively small) leakage current iᵣ via the insulation resistance R, for example, according to the following formulas (2a) and (2b):

$$Δ u = u ( t 2 ) - u ( t 1 ) U 2 - U 1 \qquad ( 2 a )$$

$$C = Q / Δ u \qquad ( 2 b )$$

Δu corresponds to a difference between the first and the second voltage value U1, U2 or the values u (t1), u (t2) of the measurement voltage uₘ measured at times t1, t2. The capacitance value C is then determined by dividing the electrical charge Q determined in the first determination step 101 by the voltage difference Δu.

Alternatively, or for a more precise determination of the capacitance C, the determination of the charge in the first determination step 101 can also be carried out over two voltage ranges. This can be of particular interest if, for example, the HV system 2 to be tested is not purely capacitive or not largely capacitive. For example, a relatively large proportion of the measured current iₘ or the determined charge Q may also be caused by a current across a (rather low-ohmic) resistor in the HV system 2 that is parallel to the capacitor C. For this purpose, in addition to the first and second voltage values U1, U2, a further, third voltage value U3 is predetermined, which is greater than the first voltage value U1 and less than the second voltage value U2. The third voltage value U3 could be 50% of the target value Uₜ of the test voltage, for example. In the first determination step 101, an electrical charge between the first and the third voltage value U1, U3 and an electrical charge between the third and the second voltage value U3, U2 are then determined according to the above-mentioned formula (1). For this purpose, the measurement current iₘ is integrated between the points in time at which the first and third voltage values U1, U3 respectively the third and second voltage values U3, U2 are measured by the voltmeter V.

In the estimation step 102, a capacitance value C of the HV system 2 to be tested or of the component to be tested is then estimated from the charge values determined for the two voltage ranges—i.e., the range between the first and third voltage values U1, U3 and the range between the third and second voltage values U3, U2. The estimated capacitance values C are then compared with each other. If the two estimated capacitance values C are approximately identical, then a largely capacitive HV system 2 or a largely capacitive component is present. The capacitance value C estimated in estimation step 2 using one of the two voltage ranges can then be used for a further course of the method. If the two capacitance values C estimated in estimation step 102 differ significantly from each other, the HV system 2 to be tested is neither purely capacitive nor largely capacitive. For the further course of the method, for example, an arithmetic mean of the two estimated capacitance values C can be used. In addition, the estimation of the capacitance value C with the help of two voltage ranges can also be used to better adjust or regulate the voltage source 4 to the HV system 2 to be tested or the component to be tested.

In a second determination step 103, during the measuring phase MP in the evaluation unit 5, a correction current i_{dr} is determined from the capacitance value C estimated in the estimation step 102 and from a temporal deviation of the measured measurement voltage uₘ from the predefined target value Uₜ of the test voltage. The measuring phase MP starts—as shown in FIG. 3—at a time tₘ at which the target value Uₜ is reached and is kept constant except for the deviations due to the voltage drift u_{dr}. The correction current i_{dr} is determined according to the following formula (3).

$${i}_{dr} ( t ) = C * du ( t ) / dt \qquad ( 3 )$$

Here, C is the estimated capacitance value C and u(t) corresponds to the measured voltage uₘ, which can be determined by the voltmeter V, e.g., continuously or in the form of time-discretely sampled measured values. du(t)/dt then represents the deviation of the measured voltage uₘ from the predefined constant target value Uₜ of the test voltage or the voltage drift u_{dr}. The correction current i_{dr} determined by the evaluation unit 5 is then used to correct the measured current iₘ. According to formula (4), this results in a corrected measurement current iₖₒᵣᵣ as the difference between the measured measurement current iₘ and determined correction current i_{dr}.

$${i}_{korr} ( t ) = {i}_{m} ( t ) - {i}_{dr} ( t ) \qquad ( 4 )$$

In a derivation step 104, the evaluation unit 5 then derives the insulation resistance R from the corrected measurement current iₖₒᵣᵣ and the measured voltage uₘ. For this purpose, for example, Ohm's law can be used, wherein, for example, the measured measurement voltage uₘ is divided by the currently determined value of the correction current iₖₒᵣᵣ. The individual results of this resistance determination can then be filtered or averaged.

Temporal courses of the measured measurement voltage uₘ, of the measured measurement current iₘ, of the correction current iₖₒᵣᵣ and of the corrected measurement current i_{dr} during the measuring phase or during the second determination step 103 and the derivation step 104 are shown as examples in FIG. 4. For example, it was assumed that an HV system 2 to be tested or a component 2 to be tested had a relatively large capacitance C (e.g., 1 μFarad) and a parallel resistance R in the high-ohmic range (e.g., 1 GΩ). Furthermore, FIG. 4 shows an example of a temporal course of the resistance R derived in the derivation step 104 from the corrected measurement current iₖₒᵣᵣ. The first temporal course shows an enlarged representation of the exemplary temporal course of the measurement voltage uₘ from FIG. 3, in order, above all, to better illustrate the deviations due to the voltage drift u_{dr}. The second temporal course shows the temporal course of the measured measurement current iₘ, the correction current i_{dr} and the corrected measurement current iₖₒᵣᵣ, wherein the x-axis again represents the time t in seconds. The current i (e.g., in μAmperes) is plotted on the y-axis. It is also clear from FIG. 4 that the course of the originally measured measurement current iₘ may exhibit fluctuations that are larger than the average measured current itself. The calculated current share i_{dr} can effectively reduce these fluctuations—caused by the drift voltage u_{dr} of the voltage source 4—as can be seen from the course of the corrected measurement current iₖₒᵣᵣ. The third course then shows a temporal course of the derived resistance R, wherein the y-axis is in GQ, for example.

After the derivation step 104, the derived insulation resistance R can then be output in an output step 105, for example on a display unit 6. This can be done, for example, as a representation in the form of a resistance value in megaohms and/or in relation to the voltage in ohms/volt. Furthermore, an evaluation of the derived insulation resistance R (e.g., insulation resistance R sufficient, insulation resistance R too small, etc.) can be output and displayed on the display unit 6 in the output step 105.

1. A method for determining an insulation resistance in a high-voltage system, wherein a test voltage with a predefined constant target value is applied to the high-voltage system to be tested or a component to be tested, and wherein a measurement current caused by the test voltage and a measurement voltage currently present on the high-voltage system to be tested or on the component to be tested are measured, wherein an electrical charge of the high-voltage system to be tested or of the component to be tested is determined during a ramp-up of the test voltage to the predefined constant target value, wherein a capacitance value for the high-voltage system to be tested or the component to be tested is estimated from the determined charge, wherein during a measuring phase a correction current is determined from the estimated capacitance value and from a temporal deviation of the measured measurement voltage from the predefined target value of the test voltage, the correction current being used to correct the respective measured measurement current, and wherein the insulation resistance is derived from the corrected measurement current and the measured measurement voltage.

2. The method according to claim 1, wherein the electrical charge of the high-voltage system to be tested or the component to be tested is determined by integrating the measured measurement current.

3. Method according to claim 1, wherein for estimating the capacitance value of the high-voltage system to be tested or the component to be tested, a first and a second voltage value of the measurement voltage are predetermined, between which the electrical charge of the high-voltage system to be tested or the component to be tested is determined.

4. Method according to claim 3, wherein for estimating the capacitance value of the high-voltage system to be tested or the component to be tested, a third voltage value of the measurement voltage is predetermined, which is greater than the first voltage value of the measurement voltage and less than the second voltage value of the measurement voltage, wherein the electrical charge of the high-voltage system to be tested or the component to be tested between the first and the third voltage value and the electrical charge of the high-voltage system to be tested or the component to be tested between the third and the second voltage value is determined, and wherein a capacitance value of the high-voltage system to be tested or the component to be tested is estimated from the determined charges.

5. Method according to claim 1, wherein at least the derived insulation resistance is output and displayed.

6. Method according to claim 1, wherein a measurement of the measurement current and a measurement of the measurement voltage is carried out simultaneously.

7. Method according to claim 1, wherein during ramp-up of the test voltage to the predefined constant target value, a temporal change in the measurement voltage applied to the high-voltage system to be tested or to the component to be tested is limited when the test voltage is ramping up to the predefined target value.

8. Method according to claim 1, wherein the measurement of the measurement current or the measurement voltage is continuous.

9. Method according to claim 1, wherein the measurement of the measurement current or the measurement voltage is performed by time-discrete sampling.

10. Measuring system for determining an insulation resistance in a high-voltage system, wherein the measuring system can be connected to the high-voltage system to be tested or to a component of the high-voltage system to be tested, and wherein the measuring system has at least one voltage source for generating a test voltage with a predefined constant target value, an ammeter for measuring a measurement current caused by the test voltage, and a voltmeter for measuring a measurement voltage applied to the high-voltage system to be tested or the component to be tested, wherein the measuring system further comprises an evaluation unit, which is configured to determine an electrical charge of the high-voltage system to be tested or the component to be tested during a ramp-up of the test voltage to the predefined constant target value, and to estimate a capacitance value of the high-voltage system to be tested or the component to be tested from the determined charge, and which evaluation unit is furthermore configured to estimate a correction current for correcting the measurement current, measured by the ammeter, from the determined capacitance value and from a temporal deviation of the measurement voltage measured by the voltmeter from the predefined constant target value of the test voltage during a measuring phase, and to derive the insulation resistance from the corrected measurement current and the measured measurement voltage.

11. Measuring system according to claim 10, wherein a display unit is provided for displaying at least the insulation resistance derived from the corrected measurement current.

12. Measuring system according to claim 10, wherein a measured value acquisition by the ammeter and by the voltmeter as well as the evaluation unit are microcontroller-based.
